(19) United States
(12) Patent Application Publication
(10) Pub. No.: US 2012/0025212 A1
(43) Pub. Date: Feb. 2, 2012

(54) GeSn Infrared Photodetectors

(75) Inventors: John Kouvetakis, Mesa, AZ (US); Jose Menendez, Tempe, AZ (US); Radek Roucka, Tempe, AZ (US); Jay Mathews, Tempe, AZ (US)

(73) Assignee: Arizona Board of Regents, a body corporate acting for and on behalf of Arizona State University, Scottsdale, AZ (US)

(21) Appl. No.: 13/062,154

(22) PCT Filed: Sep. 16, 2009
(86) PCT No.: PCT/US09/57218

§ 371 Date: Oct. 17, 2011

Related U.S. Application Data
(60) Provisional application No. 61/097,272, filed on Sep. 16, 2008.
(60) Provisional application No. 61/105,670, filed on Oct. 15, 2008.

(51) Int. Cl. H01L 33/02; H01L 31/107; H01L 31/18; H01L 31/102

(52) U.S. Cl. 257/85; 257/184; 257/186; 438/94; 257/E33.076; 257/E31.064; 257/E31.055

(57) ABSTRACT

Photodiode devices with GeSn active layers can be integrated directly on p+ Si platforms under CMOS-compatible conditions. It has been found that even minor amounts of Sn incorporation (2%) dramatically expand the range of IR detection up to at least 1750 nm and substantially increases the absorption. The corresponding photoresponse can cover of all telecommunication bands using entirely group IV materials.

### CROSS-REFERENCE TO RELATED APPLICATIONS

This application claims the benefit of the filing date of U.S. Provisional Application Ser. No. 61/097,272, filed Sep. 16, 2008, and U.S. Provisional Application Ser. No. 61/105,670, filed Oct. 15, 2008, each of which is hereby incorporated by reference in their entirety.

### STATEMENT OF GOVERNMENT FUNDING

The invention described herein was made in part with government support under grant number DEFG3608GO18003, awarded by the Department of Energy; and grant number FA9550-06-01-0442 awarded by the United States Air Force Office of Scientific Research (AFOSR). The United States Government has certain rights in the invention.

### FIELD OF THE INVENTION

The invention generally relates to infrared photodetectors comprising Group IV semiconductor layers.

### BACKGROUND OF THE INVENTION

The application of silicon photonic technologies to optical telecommunications requires the development of near-infrared detectors monolithically integrated to the Si platform. Ge₁₋ₓSiₓ alloys can grow fully strained on Si with defect-free heterointerfaces, but their critical thickness is reduced to unacceptably low values as the Si-concentration x is reduced to bring their optical absorption edge closer to the needed infrared range. Accordingly, efforts in this area have focused on developing non-pseudomorphic pure-Ge detectors on Si. This is a challenging task due to the inferior crystalline quality and high dislocation densities in Ge/Si layers resulting from the 4% lattice mismatch between the two materials. Recent approaches to minimize the effect of dislocations. include the use of intermediate graded Ge₁₋ₓSiₓ layers (see, Currie, M. T. et al., Appl. Phys. Lett. 72, 1718 (1998)) and the growth of a low-temperature Ge initiation layer (see, Hsin-Chiao, L et al., Appl. Phys. Lett. 75, 2909 (1999)). Unfortunately, even pure Ge is only marginally acceptable as a near infrared detector, since its direct absorption edge at 1550 nm is in the middle of the “erbium window” (C-band), and its responsivity is drastically reduced at wavelengths corresponding to the L- and U-telecommunication windows, for which only indirect gap absorption is possible. The absorption edge of Ge on Si substrates has been recently extended further into the infrared by exploiting the tensile strain that develops at room temperature after strain relaxation at high temperatures (see, Liu, J. et al., Appl. Phys. Lett. 87, 103501 (2005); and Wang, J. et al. in 2007 4th IEEE International Conference on Group IV Photonics, (2007), p. 1). However, this approach increases the thermal budget, compromising the compatibility with CMOS technology, and still fails to fully cover the L- and U-bands.

### SUMMARY OF THE INVENTION

The creation and performance evaluation of infrared photodiode devices with GeSn active layers are provided herein. These systems can be integrated, for example, directly on p+ Si platforms under CMOS-compatible conditions.

It has been found that even minor amounts of Sn incorporation (2%) can dramatically expand the range of IR detection up to at least 1750 nm, well below the direct bandgap of Ge (1550 nm), and substantially increase the optical absorption. The corresponding photoresponse can yield higher quantum efficiencies than comparable pure-Ge devices over a broader spectrum, allowing coverage of all telecommunication bands using entirely group IV materials.

In a first aspect, the invention provides infrared detectors comprising a substrate comprising a Si surface layer; an optional first Ge₁₋ₓSnₓ layer formed directly over the Si surface layer; an optional intrinsic Ge₁₋ₓSnₓ layer formed directly over the Si surface layer or, when present, the first Ge₁₋ₓSnₓ layer; and a second Ge₁₋ₓSnₓ layer formed directly over, when present, the intrinsic Ge₁₋ₓSnₓ layer or, when present, the first Ge₁₋ₓSnₓ layer, or the Si surface layer; wherein one of (i) the Si surface layer or the first Ge₁₋ₓSnₓ layer and (ii) the second Ge₁₋ₓSnₓ layer is p-doped and the other of (i) and (ii) is n-doped, provided that when the Si surface layer is doped and the first Ge₁₋ₓSnₓ layer is present, then the Si surface layer and the first Ge₁₋ₓSnₓ layer are both n-doped or are both p-doped.

In another aspect, the invention provides avalanche photodetectors comprising an infrared detector according to any embodiment of the first aspect.

In another aspect, the invention provides photonic circuit elements comprising an infrared detector according to any embodiment of the first aspect, and a waveguiding structure in optical communication with the infrared detector.

In another aspect, the invention provides detector arrays comprising a plurality of infrared detector elements according to the first aspect of the invention arranged in an predetermined arrangement.

In another aspect, the invention provides methods for fabricating infrared detectors comprising providing a substrate comprising a Si surface layer; optionally forming a first doped Ge₁₋ₓSnₓ layer over the Si surface layer; optionally forming an intrinsic Ge₁₋ₓSnₓ layer over the Si surface layer or, when present, the first doped Ge₁₋ₓSnₓ layer; and forming a second doped Ge₁₋ₓSnₓ layer over the intrinsic Ge₁₋ₓSnₓ layer, when present, or the first doped Ge₁₋ₓSnₓ layer, when present, or the Si surface layer; wherein one of (i) the Si surface layer or the first doped Ge₁₋ₓSnₓ layer and (ii) the second doped Ge₁₋ₓSnₓ layer is p-doped and the other of (i) and (ii) is n-doped, provided that when the Si surface layer is doped and the first doped Ge₁₋ₓSnₓ layer is present, then the Si surface layer and the first doped Ge₁₋ₓSnₓ layer are both n-doped or are both p-doped.

### BRIEF DESCRIPTION OF THE DRAWINGS

FIG. 1 shows a SIMS profile of a PIN heterostructure of Example 2 comprising an n-type top layer doped with P at 1×10²⁰ cm⁻³, the intrinsic Ge_{0.98}Sn_{0.02} middle layer devoid of B and P impurities, and the underlying Si(100) doped with B at 4.3×10¹⁹ cm⁻³.

FIG. 2a shows a cross sectional schematic of the photodiode stack including the SiO₂ top window, sidewalls and metallic contacts.

FIG. 2b shows a plan-view optical image showing the various mesas (60 μm-300 μm an in diameter) and associated metallic structures.

FIG. 3 shows current-voltage (IV) graphs obtained from six device mesas with diameters ranging from 60 μm to 300 μm an indicating that the dark currents increases monotonically with the device size.

FIG. 4 is a graph of external quantum efficiencies versus wavelength of the photodiode indicating that the IR detection response spans all telecommunication bands up to 1750 nm. The mesas are vertically illuminated using a continuous halogen source (solid line) and several laser diodes at 1270, 1300, 1550 and 1620 nm (squares).

FIG. 5 is a graph illustrating the absorption coefficient of Ge₁₋ₓSnₓ. Inset: absorption coefficients of Ge_{0.98}Sn_{0.02} and pure Ge showing a tenfold increase of absorption at 1.55 μm.

FIG. 6 is a schematic of the fabricated prototype photodetector of Example 3.

### DETAILED DESCRIPTION OF THE INVENTION

The term “layer” as used herein, means a continuous region of a material (e.g., an alloy) that can be uniformly or non-uniformly doped and that can have a uniform or a non-uniform composition across the region.

The term “p-doped” as used herein means atoms have been added to the material to increase the number of free positive charge carriers.

The term “n-doped” as used herein means atoms have been added to the material to increase the number of free negative charge carriers.

The term “semi-insulating” as used herein means the referenced item has a resistivity of greater than about 10⁷ ohm-cm.

The term “active carrier concentration” as used herein means the concentration of free holes or free electrons in p-doped and n-doped materials, respectively. Such free concentrations are not necessarily the same as the concentration of a dopant in the material; that is, the activation energy associated with dopants can define the percentage of such dopant which is free and can contribute to conduction.

Two elements are in “electrical contact” as used herein when the first referenced element is positioned with respect to the second element such that an electrical current can pass between the two elements upon application of a potential across the two elements.

The term “photoresponse” as used herein means that upon exposure of the structure or device to light at the referenced wavelength, then the structure or device produces an electrical response or output (e.g., current). When a photoresponse is quoted for a wavelength range, then the referenced item displays the photoresponse in at least 90% of the quoted range, preferably, at least 95% of the quoted range, and more preferably, at least 98% of the quoted range. For example, for a photoresponse within the range from 1000 nm to 1750 nm, then an item displaying a response from 1000 nm to 1675 nm (i.e., 90% of the range) satisfies the requirement. Such 90% portion of the range may start at either end (e.g., 1075 nm-1750 nm) of the range, or be wholly contained within the range (e.g., 1025 nm-1700 nm). Such 90% portion may also be discontinuous within the range, for example, a photoresponse from 1000 nm to 1050 nm and 1100 nm-1725 nm.

The term “external quantum efficiency” as used herein means the fraction of photons hitting the device that are converted to electron-hole pairs, where the generation of electron-hole pairs is independent of any subsequent photoresponse, as defined herein, in response to the exposure. When a required external quantum efficiency is quoted for a wavelength range, then the referenced item displays the required external quantum efficiency in at least 90% of the quoted range, preferably, at least 95% of the quoted range, and more preferably, at least 98% of the quoted range. For example, for a required external quantum efficiency within the range from 1625 nm-1675 nm, then an item displaying the required external quantum efficiency from 1625 nm to 1670 nm (i.e., 90% of the range) satisfies the requirement. Such 90% portion of the range may start at either end (e.g., 1630-1675 nm) of the range, or be wholly contained within the range (e.g., 1628 nm-1673 nm). Such 90% portion may also be discontinuous within the range, for example, a required response from 1625 nm to 1650 nm and 1655 nm-1675 nm.

The term “intrinsic semiconductor” as used herein means a semiconductor material in which the concentration of charge carriers is characteristic of the material itself rather than the content of impurities (or dopants).

The term “compensated semiconductor” refers to a semiconductor material in which one type of impurity (or imperfection, for example, a donor atom) partially (or completely) cancels the electrical effects on the other type of impurity (or imperfection, for example, an acceptor atom).

It should be understood that when a layer is referred to as being “on” or “over” another layer or substrate, it can be directly on the layer or substrate, or an intervening layer may also be present. It should also be understood that when a layer is referred to as being “on” or “over” another layer or substrate, it may cover the entire layer or substrate, or a portion of the layer or substrate.

It should be further understood that when a layer is referred to as being “directly on” or “directly over” another layer or substrate, the two layers are in direct contact with one another with no intervening layer. It should also be understood that when a layer is referred to as being “directly on” or “directly over” another layer or substrate, it may cover the entire layer or substrate, or a portion of the layer or substrate.

In the first aspect, the invention provides infrared detectors comprising a substrate comprising a Si surface layer; an optional first Ge₁₋ₓSnₓ layer formed directly over the Si surface layer; an optional intrinsic Ge₁₋ₓSnₓ layer formed directly over the Si surface layer or, when present, the first Ge₁₋ₓSnₓ layer; and a second Ge₁₋ₓSnₓ layer formed directly over, when present, the intrinsic Ge₁₋ₓSnₓ layer or, when present, the first Ge₁₋ₓSnₓ layer, or the Si surface layer; wherein one of (i) the Si surface layer or the first Ge₁₋ₓSnₓ layer and (ii) the second Ge₁₋ₓSnₓ layer is p-doped and the other of (i) and (ii) is n-doped, provided that when the Si surface layer is doped and the first Ge₁₋ₓSnₓ layer is present, then the Si surface layer and the first Ge₁₋ₓSnₓ layer are both n-doped or are both p-doped.

In one preferred embodiment, the infrared detectors comprise a substrate comprising a Si surface layer, an optional first Ge₁₋ₓSnₓ layer formed directly over the Si surface layer; an intrinsic Ge₁₋ₓSnₓ layer formed directly over the Si surface layer or, when present, the first Ge₁₋ₓSnₓ layer; and a second Ge₁₋ₓSnₓ layer formed directly over the intrinsic Ge₁₋ₓSnₓ layer, wherein one of (i) the Si surface layer or the first Ge₁₋ₓSnₓ layer and (ii) the second Ge₁₋ₓSnₓ layer is p-doped and the other of (i) and (ii) is n-doped, provided that when the Si surface layer is doped and the first Ge₁₋ₓSnₓ layer is present, then the Si surface layer and the first Ge₁₋ₓSnₓ layer are both n-doped or are both p-doped.

In one preferred embodiment, the infrared detectors comprise a substrate comprising a Si surface layer, a first Ge₁₋ₓSnₓ layer formed directly over the Si surface layer; an intrinsic Ge₁₋ₓSnₓ layer formed directly over the first Ge₁₋ₓSnₓ layer; and a second Ge₁₋ₓSnₓ layer formed directly over the intrinsic Ge₁₋ₓSnₓ layer, wherein one of the first Ge₁₋ₓSnₓ layer and the second Ge₁₋ₓSnₓ layer is p-doped and the other of the first Ge₁₋ₓSnₓ layer and the second Ge₁₋ₓSnₓ layer is n-doped, provided that when the Si surface layer is doped, then the Si surface layer and the first Ge₁₋ₓSnₓ layer are both n-doped or are both p-doped.

In another preferred embodiment, the infrared detectors comprise a substrate comprising a Si surface layer, a first n-doped Ge₁₋ₓSnₓ layer formed directly over the Si surface layer; an intrinsic Ge₁₋ₓSnₓ layer formed directly over the first n-doped Ge₁₋ₓSnₓ layer; and a second p-doped Ge₁₋ₓSnₓ layer formed directly over the intrinsic Ge₁₋ₓSnₓ layer, provided that when the Si surface layer is doped, then the Si surface layer is n-doped.

In another preferred embodiment, the infrared detectors comprise a substrate comprising an n-doped Si surface layer, a first n-doped Ge₁₋ₓSnₓ layer formed directly over the Si surface layer; an intrinsic Ge₁₋ₓSnₓ layer formed directly over the first n-doped Ge₁₋ₓSnₓ layer; and a second p-doped Ge₁₋ₓSnₓ layer formed directly over the intrinsic Ge₁₋ₓSnₓ layer.

In another preferred embodiment, the infrared detectors comprise a substrate comprising a Si surface layer, a first p-doped Ge₁₋ₓSnₓ layer formed directly over the Si surface layer; an intrinsic Ge₁₋ₓSnₓ layer formed directly over the first p-doped Ge₁₋ₓSnₓ layer; and a second n-doped Ge₁₋ₓSnₓ layer formed directly over the intrinsic Ge₁₋ₓSnₓ layer, provided that when the Si surface layer is doped, then the Si surface layer is p-doped.

In another preferred embodiment, the infrared detectors comprise a substrate comprising a p-doped Si surface layer, a first p-doped Ge₁₋ₓSnₓ layer formed directly over the Si surface layer; an intrinsic Ge₁₋ₓSnₓ layer formed directly over the first p-doped Ge₁₋ₓSnₓ layer; and a second n-doped Ge₁₋ₓSnₓ layer formed directly over the intrinsic Ge₁₋ₓSnₓ layer.

In another preferred embodiment, the infrared detectors comprise a substrate comprising a Si surface layer; an intrinsic Ge₁₋ₓSnₓ layer formed directly over the Si surface layer; and a second Ge₁₋ₓSnₓ layer formed directly over the intrinsic Ge₁₋ₓSnₓ layer, wherein one of the Si surface layer and the second Ge₁₋ₓSnₓ layer is p-doped and the other of the Si surface layer and the second Ge₁₋ₓSnₓ layer is n-doped.

In another preferred embodiment, the infrared detectors comprise a substrate comprising a p-doped Si surface layer; an intrinsic Ge₁₋ₓSnₓ layer formed directly over the Si surface layer; and a second n-doped Ge₁₋ₓSnₓ layer formed directly over the intrinsic Ge₁₋ₓSnₓ layer.

In another preferred embodiment, the infrared detectors comprise a substrate comprising an n-doped Si surface layer; an intrinsic Ge₁₋ₓSnₓ layer formed directly over the Si surface layer; and a second p-doped Ge₁₋ₓSnₓ layer formed directly over the intrinsic Ge₁₋ₓSnₓ layer.

In another preferred embodiment, the infrared detectors comprise a substrate comprising a Si surface layer, an optional first Ge₁₋ₓSnₓ layer formed directly over the Si surface layer; and a second Ge₁₋ₓSnₓ layer formed directly over, when present, the first Ge₁₋ₓSnₓ layer, or the Si surface layer, wherein one of (i) the Si surface layer or the first Ge₁₋ₓSnₓ layer and (ii) the second Ge₁₋ₓSnₓ layer is p-doped and the other of (i) and (ii) is n-doped, provided that when the Si surface layer is doped and the first Ge₁₋ₓSnₓ layer is present, then the Si surface layer and the first Ge₁₋ₓSnₓ layer are both n-doped or are both p-doped.

In another preferred embodiment, the infrared detectors comprise a substrate comprising a Si surface layer, a first Ge₁₋ₓSnₓ layer formed directly over the Si surface layer; and a second Ge₁₋ₓSnₓ layer formed directly over the first Ge₁₋ₓSnₓ layer, wherein one of (i) the first Ge₁₋ₓSnₓ layer and (ii) the second Ge₁₋ₓSnₓ layer is p-doped and the other of (i) and (ii) is n-doped, provided that when the Si surface layer is doped, then the Si surface layer and the first Ge₁₋ₓSnₓ layer are both n-doped or are both p-doped.

In another preferred embodiment, the infrared detectors comprise a substrate comprising a Si surface layer, a first p-doped Ge₁₋ₓSnₓ layer formed directly over the Si surface layer; and a second n-doped Ge₁₋ₓSnₓ layer formed directly over the first p-doped Ge₁₋ₓSnₓ layer, provided that when the Si surface layer is doped, then the Si surface layer and the first Ge₁₋ₓSnₓ layer are both p-doped.

In another preferred embodiment, the infrared detectors comprise a substrate comprising a Si surface layer, a first n-doped Ge₁₋ₓSnₓ layer formed directly over the Si surface layer; and a second p-doped Ge₁₋ₓSnₓ layer formed directly over the first n-doped Ge₁₋ₓSnₓ layer, provided that when the Si surface layer is doped, then the Si surface layer and the first Ge₁₋ₓSnₓ layer are both n-doped.

In another preferred embodiment, the infrared detectors comprise a substrate comprising a doped Si surface layer, and a second doped Ge₁₋ₓSnₓ layer formed directly over, the doped Si surface layer, wherein one of (i) the doped Si surface layer and (ii) the second doped Ge₁₋ₓSnₓ layer is p-doped and the other of (i) and (ii) is n-doped.

In another preferred embodiment, the infrared detectors comprise a substrate comprising a p-doped Si surface layer, and a second n-doped Ge₁₋ₓSnₓ layer formed directly over, the p-doped Si surface layer.

In another preferred embodiment, the infrared detectors comprise a substrate comprising a n-doped Si surface layer, and a second p-doped Ge₁₋ₓSnₓ layer formed directly over, the n-doped Si surface layer.

The substrate can be any suitable element which has at least one Si surface layer onto which the various Ge₁₋ₓSnₓ layers can be formed. The Si surface layer itself consists essentially of Si, such as Si(100). The Si surface layer can be n-doped Si, p-doped Si, semi-insulating Si, intrinsic Si, compensated Si, provided that the requirements of the first aspect are satisfied as noted above. In certain preferred embodiments, the substrate is an intrinsic Si substrate, a compensated Si substrate, a semi-insulating Si substrate, or a silicon-on-insulator (SOI) substrate (e.g., single-faced Si surface layer on SiO₂ or double-faced Si with a first and second Si surface layer each over an embedded SiO₂ layer). In another preferred embodiment, the substrate is a Si(100) wafer, i.e., an n-doped Si(100) wafer, a p-doped Si(100) wafer, semi-insulating Si(100) wafer, a compensated Si(100) wafer, or an intrinsic Si(100) wafer.

The Si surface layer can be of any thickness suitable for a given purpose. For example, the Si surface layer can have a thickness ranging from about 100 nm to about 1 mm. In preferred embodiments, the Si surface layer has thickness between about 100 nm and about 1000 nm, or about 100 nm and about 900 nm, or about 100 nm and about 800 nm, or about 100 nm and about 700 nm, or about 100 nm and about 600 nm, or about 100 nm and about 500 nm or about 100 nm and about 400 nm, or about 100 nm and about 300 nm, or about 100 nm and about 200 nm. In other preferred embodiments where the substrate is a Si wafer, then the Si surface layer can have the same thickness as that of the Si wafer itself, for example, the Si wafer can have a thickness between about 1 μm and about 1 mm, about 1 μm and about 800 μm, or about 100 μm and about 800 μm, or about 200 μm and about 1 mm; or about 200 μm and about 800 μm.

The substrate can be of any size suitable for a given purpose. For example, when the substrate is a Si(100) wafer or a SOI substrate, the substrate can be circular and have a diameter of at least 1 inch, or at least 3 inches, or at least 4 inches, or at least 6 inches. For example, the substrate can have a diameter of about 1 inch to about 12 inches, or about 3 to about 12 inches, or about 6 inches to about 12 inches. In other examples, the substrate can have a diameter of about 8 inches to about 12 inches. In other examples, the substrate can have a diameter of about 100 mm to about 500 mm, or about 100 mm to about 300 mm, or about 100 mm to about 200 mm. In other examples, the substrate is a square Si(100) wafer having dimensions of about 100 mm×100 mm, or about 200×200 mm, or about 150 mm×150 mm, or about 160 mm×160 mm.

In another preferred embodiment, the infrared detectors comprise a substrate comprising an intrinsic Si or compensated Si surface layer, a first n-doped Ge₁₋ₓSnₓ layer formed directly over the Si surface layer; an intrinsic Ge₁₋ₓSnₓ layer formed directly over the first n-doped Ge₁₋ₓSnₓ layer; and a second p-doped Ge₁₋ₓSnₓ layer formed directly over the intrinsic Ge₁₋ₓSnₓ layer.

In another preferred embodiment, the infrared detectors comprise a substrate comprising an intrinsic Si or compensated Si surface layer, a first p-doped Ge₁₋ₓSnₓ layer formed directly over the Si surface layer; an intrinsic Ge₁₋ₓSnₓ layer formed directly over the first p-doped Ge₁₋ₓSnₓ layer; and a second n-doped Ge₁₋ₓSnₓ layer formed directly over the intrinsic Ge₁₋ₓSnₓ layer.

The first, intrinsic, and second Ge₁₋ₓSnₓ layers can each comprise, consist, or consist essentially of a Ge₁₋ₓSnₓ alloy wherein x is about 0.01 to about 0.20. In a preferred embodiment, each Ge₁₋ₓSnₓ layer can comprise, consist, or consist essentially of a Ge₁₋ₓSnₓ alloy wherein x is about 0.01 to about 0.19, or about 0.01 to about 0.18, or about 0.01 to about 0.17, or about 0.01 to about 0.16, or about 0.01 to about 0.15, or about 0.01 to about 0.14, or about 0.01 to about 0.13, or about 0.01 to about 0.12, or about 0.01 to about 0.11, or about 0.01 to about 0.10, or about 0.01 to about 0.09, or about 0.01 to about 0.08, or about 0.01 to about 0.07, or about 0.01 to about 0.06, or about 0.01 to about 0.05.

In another preferred embodiment, the first, intrinsic, and second Ge₁₋ₓSnₓ layers can each comprise, consist, or consist essentially of a Ge₁₋ₓSnₓ alloy wherein x is about 0.02 to about 0.19, or about 0.02 to about 0.18, or about 0.02 to about 0.17, or about 0.02 to about 0.16, or about 0.02 to about 0.15, or about 0.02 to about 0.14, or about 0.02 to about 0.13, or about 0.02 to about 0.12, or about 0.02 to about 0.11, or about 0.02 to about 0.10, or about 0.02 to about 0.09, or about 0.02 to about 0.08, or about 0.02 to about 0.07, or about 0.02 to about 0.06, or about 0.02 to about 0.05.

In another preferred embodiment, the first, intrinsic, and second Ge₁₋ₓSnₓ layers can each comprise, consist, or consist essentially of a Ge₁₋ₓSnₓ alloy wherein x is about 0.03 to about 0.19, or about 0.03 to about 0.18, or about 0.03 to about 0.17, or about 0.03 to about 0.16, or about 0.03 to about 0.15, or about 0.03 to about 0.14, or about 0.03 to about 0.13, or about 0.03 to about 0.12, or about 0.03 to about 0.11, or about 0.03 to about 0.10, or about 0.03 to about 0.09, or about 0.03 to about 0.08, or about 0.03 to about 0.07, or about 0.03 to about 0.06, or about 0.03 to about 0.05.

In another preferred embodiment, the first, intrinsic, and second Ge₁₋ₓSnₓ layers can each comprise, consist, or consist essentially of a Ge₁₋ₓSnₓ alloy wherein x is about 0.04 to about 0.19, or about 0.04 to about 0.18, or about 0.04 to about 0.17, or about 0.04 to about 0.16, or about 0.04 to about 0.15, or about 0.04 to about 0.14, or about 0.04 to about 0.13, or about 0.04 to about 0.12, or about 0.04 to about 0.11, or about 0.04 to about 0.10, or about 0.04 to about 0.09, or about 0.04 to about 0.08, or about 0.04 to about 0.07, or about 0.04 to about 0.06, or about 0.04 to about 0.05.

In another preferred embodiment, the first, intrinsic, and second Ge₁₋ₓSnₓ layers can each comprise, consist, or consist essentially of a Ge₁₋ₓSnₓ alloy wherein x about 0.05 to about 0.19, or about 0.05 to about 0.18, or about 0.05 to about 0.17, or about 0.05 to about 0.16, or about 0.05 to about 0.15, or about 0.05 to about 0.14, or about 0.05 to about 0.13, or about 0.05 to about 0.12, or about 0.05 to about 0.11, or about 0.05 to about 0.10, or about 0.05 to about 0.09, or about 0.05 to about 0.08, or about 0.05 to about 0.07, or about 0.05 to about 0.06.

In another preferred embodiment, the first, intrinsic, and second Ge₁₋ₓSnₓ layers can each comprise, consist, or consist essentially of a Ge₁₋ₓSnₓ alloy wherein x is about 0.02 to about 0.20, or about 0.03 to about 0.20, or about 0.04 to about 0.20, or about 0.05 to about 0.20, or about 0.06 to about 0.20, or about 0.07 to about 0.20, or about 0.08 to about 0.20, or about 0.09 to about 0.20, or about 0.10 to about 0.20, or about 0.11 to about 0.20, or about 0.12 to about 0.20, or about 0.13 to about 0.20, or about 0.14 to about 0.20, or about 0.15 to about 0.20. In yet another example, the first, intrinsic, and second Ge₁₋ₓSnₓ layers can comprise, consist, or consist essentially of a Ge₁₋ₓSnₓ layer wherein x is about 0.01 to about 0.05, or about 0.05 to about 0.10, or about 0.05 to about 0.15, or about 0.05 to about 0.20.

In another preferred embodiment, the first, intrinsic, and second Ge₁₋ₓSnₓ layers can each comprise, consist, or consist essentially of a Ge₁₋ₓSnₓ alloy wherein x is about 0.01 to about 0.10. In another preferred embodiment, the first, intrinsic, and second Ge₁₋ₓSnₓ layers can each comprise, consist, or consist essentially of a Ge₁₋ₓSnₓ alloy wherein x is about 0.01 to about 0.05. In another preferred embodiment, the first, intrinsic, and second Ge₁₋ₓSnₓ layers can each comprise, consist, or consist essentially of a Ge₁₋ₓSnₓ alloy wherein x is about 0.02. In certain preferred embodiments of any of the preceding embodiments, the first, intrinsic, and second Ge₁₋ₓSnₓ layers each comprise, consist, or consist essentially of a Ge₁₋ₓSnₓ alloy wherein x is essentially the same.

The first Ge₁₋ₓSnₓ layer, when present, can have a thickness between about 10 nm to about 1000 nm. For example, in a preferred embodiment, the thickness can be between about 10 nm and about 900 nm, or about 10 nm and about 800 nm, or about 10 nm and about 700 nm, or about 10 nm and about 600 nm, or about 10 nm and about 500 nm, or about 10 nm and about 400 nm, or about 10 nm and about 300 nm, or about 10 nm and about 200 nm, or about 10 nm and about 100 nm. In other preferred embodiments, the thickness can be between about 25 nm and about 1000 nm, or about 50 nm and about 1000 nm, or about 75 nm and about 1000 nm, or about 100 nm and about 1000 nm, or about 200 nm and about 1000 nm, or about 300 nm and about 1000 nm, or about 400 nm and about 1000 nm, or about 500 nm and about 1000 nm.

The second Ge₁₋ₓSnₓ layer can have a thickness between about 10 nm to about 1000 nm. For example, in a preferred embodiment, the thickness can be between about 10 nm and about 900 nm, or about 10 nm and about 800 nm, or about 10 nm and about 700 nm, or about 10 nm and about 600 nm, or about 10 nm and about 500 nm, or about 10 nm and about 400 nm, or about 10 nm and about 300 nm, or about 10 nm and about 200 nm, or about 10 nm and about 100 nm. In other examples, the thickness can be between about 25 nm and about 1000 nm, or about 50 nm and about 1000 nm, or about 75 nm and about 1000 nm, or about 100 nm and about 1000 nm, or about 200 nm and about 1000 nm, or about 300 nm and about 1000 nm, or about 400 nm and about 1000 nm, or about 500 nm and about 1000 nm.

In a further preferred embodiment, the first and second Ge₁₋ₓSnₓ layers can each have a thickness between about 10 nm to about 1000 nm. For example, the each can have a thickness between about 10 nm and about 900 nm, or about 10 nm and about 800 nm, or about 10 nm and about 700 nm, or about 10 nm and about 600 nm, or about 10 nm and about 500 nm, or about 10 nm and about 400 nm, or about 10 nm and about 300 nm, or about 10 nm and about 200 nm, or about 10 nm and about 100 nm. In other examples, the first and second Ge₁₋ₓSnₓ layers can each have a thickness between about 25 nm and about 1000 nm, or about 50 nm and about 1000 nm, or about 75 nm and about 1000 nm, or about 100 nm and about 1000 nm, or about 200 nm and about 1000 nm, or about 300 nm and about 1000 nm, or about 400 nm and about 1000 nm, or about 500 nm and about 1000 nm.

The intrinsic Ge₁₋ₓSnₓ layer can have a thickness between about 0.1 μm to about 10 μm. For example, the intrinsic Ge₁₋ₓSnₓ layer can have a thickness between about 0.2 μm and about 10 μm, or about 0.5 μm and about 10 μm, or about 1.0 μm and about 10 μm, or about 2 μm and about 10 μm, or about 3 μm and about 10 μm, or about 4 μm and about 10 μm, or about 5 μm and about 10 μm. In other examples, the intrinsic Ge₁₋ₓSnₓ layer can have a thickness between about 0.1 μm and about 1 μm, or about 0.2 μm and about 1 μm, or about 0.3 μm and about 1 μm, or about 0.4 μm and about 1 μm, or about 0.5 μm and about 1 μm, or about 0.6 μm and about 1 μm, or about 0.7 μm and about 1 μm, or about 0.8 μm and about 1 μm, or about 0.9 μm and about 1 μm, or about 0.1 μm and about 0.5 μm, or about 0.1 μm and about 0.4 μm, or about 0.1 μm and about 0.3 μm, or about 0.1 μm and about 0.2 μm.

In a preferred embodiment, the intrinsic Ge₁₋ₓSnₓ layer can have a thickness between about 0.1 μm and about 1 μm; and the first and second Ge₁₋ₓSnₓ layers can each have a thickness between about 10 nm to about 1000 nm. In a preferred embodiment, the intrinsic Ge₁₋ₓSnₓ layer can have a thickness between about 0.1 μm and about 1 μm; and the first and second Ge₁₋ₓSnₓ layers can each have a thickness between about 10 nm and about 200 nm. In a preferred embodiment, the intrinsic Ge₁₋ₓSnₓ layer can have a thickness between about 0.1 μm and about 0.5 μm; and the first and second Ge₁₋ₓSnₓ layers can each have a thickness between about 10 nm to about 1000 nm. In a preferred embodiment, the intrinsic Ge₁₋ₓSnₓ layer can have a thickness between about 0.1 μm and about 0.5 μm; and the first and second Ge₁₋ₓSnₓ layers can each have a thickness between about 10 nm and about 200 nm.

When the preceding Ge₁₋ₓSnₓ layers are n-doped, then they can comprise P, As, or mixtures thereof. In one preferred embodiment, n-doped Ge₁₋ₓSnₓ layers comprise P. In one preferred embodiment, n-doped Ge₁₋ₓSnₓ layers comprises As. When the preceding Ge₁₋ₓSnₓ layers are p-doped, then they can comprise B or Al. In one preferred embodiment, n-doped Ge₁₋ₓSnₓ layers comprise B.

The first Ge₁₋ₓSnₓ layer can have an active carrier concentration of about 10¹⁷ cm⁻³ to about 10²² cm⁻³. In one preferred embodiment, the first Ge₁₋ₓSnₓ layer has an active carrier concentration of about 10¹⁸ cm⁻³ to about 10²² cm⁻³. In another preferred embodiment, the first Ge₁₋ₓSnₓ layer has an active carrier concentration of about 10¹⁷ cm⁻³ to about 10²¹ cm⁻³. In another preferred embodiment, the first Ge₁₋ₓSnₓ layer has an active carrier concentration of about 10¹⁸ cm⁻³ to about 10²¹ cm⁻³.

The second Ge₁₋ₓSnₓ layer can have an active carrier concentration of about 10¹⁷ cm⁻³ to about 10²² cm⁻³. In one preferred embodiment, the second Ge₁₋ₓSnₓ layer has an active carrier concentration of about 10¹⁸ cm⁻³ to about 10²² cm⁻³. In another preferred embodiment, the second Ge₁₋ₓSnₓ layer has an active carrier concentration of about 10¹⁷ cm⁻³ to about 10²¹ cm⁻³. In another preferred embodiment, the second Ge₁₋ₓSnₓ layer has an active carrier concentration of about 10¹⁸ cm⁻³ to about 10²¹ cm⁻³.

When the Si surface layer is doped, then the Si surface layer can have an active carrier concentration of about 10¹⁷ cm⁻³ to about 10²² cm⁻³. In one preferred embodiment, the Si surface layer has an active carrier concentration of about 10¹⁸ cm⁻³ to about 10²² cm⁻³. In another preferred embodiment, the Si surface layer has an active carrier concentration of about 10¹⁷ cm⁻³ to about 10²¹ cm⁻³. In another preferred embodiment, the Si surface layer has an active carrier concentration of about 10¹⁸ cm⁻³ to about 10²¹ cm⁻³.

At least one, two, or all three of the Ge₁₋ₓSnₓ layers, can be fully relaxed as is understood by one in the art. In one preferred embodiment, the first Ge₁₋ₓSnₓ layer is relaxed. In another preferred embodiment, the first Ge₁₋ₓSnₓ layer and the intrinsic Ge₁₋ₓSnₓ layer are both relaxed. In another preferred embodiment, the first, second, and intrinsic Ge₁₋ₓSnₓ layers are each relaxed. In another preferred embodiment, the first and second Ge₁₋ₓSnₓ layers are each relaxed. In another preferred embodiment, the intrinsic and the second Ge₁₋ₓSnₓ layers are each relaxed.

In a preferred embodiment of first aspect, the infrared detectors comprises a substrate comprising a Si surface layer, a first p-doped Ge₁₋ₓSnₓ layer formed directly over the Si surface layer; an intrinsic Ge₁₋ₓSnₓ layer formed directly over the first p-doped Ge₁₋ₓSnₓ layer; and a second n-doped Ge₁₋ₓSnₓ layer formed directly over the intrinsic Ge₁₋ₓSnₓ layer, provided that when the Si surface layer is doped, then the Si surface layer is p-doped, wherein the first, intrinsic, and second Ge₁₋ₓSnₓ layers each relaxed and each comprise a Ge₁₋ₓSnₓ alloy wherein x is about 0.01 to about 0.15, and wherein the first and second Ge₁₋ₓSnₓ layers each have a thickness between about 10 nm and about 200 nm, and the intrinsic Ge₁₋ₓSnₓ layer has a thickness between about 0.1 μm and about 1 μm.

In a preferred embodiment of first aspect, the infrared detectors comprises a substrate comprising a Si surface layer, a first n-doped Ge₁₋ₓSnₓ layer formed directly over the Si surface layer; an intrinsic Ge₁₋ₓSnₓ layer formed directly over the first n-doped Ge₁₋ₓSnₓ layer; and a second p-doped Ge₁₋ₓSnₓ layer formed directly over the intrinsic Ge₁₋ₓSnₓ layer, provided that when the Si surface layer is doped, then the Si surface layer is n-doped, wherein the first, intrinsic, and second Ge₁₋ₓSnₓ layers each relaxed and each comprise a Ge₁₋ₓSnₓ alloy wherein x is about 0.01 to about 0.15, and wherein the first and second Ge₁₋ₓSnₓ layers each have a thickness between about 10 nm and about 200 nm, and the intrinsic Ge₁₋ₓSnₓ layer has a thickness between about 0.1 μm and about 1 μm.

In a preferred embodiment of first aspect, the infrared detectors comprises a substrate comprising a p-doped Si surface layer; an intrinsic Ge₁₋ₓSnₓ layer formed directly over the p-doped Si surface layer; and a second n-doped Ge₁₋ₓSnₓ layer formed directly over the intrinsic Ge₁₋ₓSnₓ layer, wherein the intrinsic and second n-doped Ge₁₋ₓSnₓ layers each relaxed and each comprise a Ge₁₋ₓSnₓ alloy wherein x is about 0.01 to about 0.15, and wherein the second n-doped Ge₁₋ₓSnₓ layer has a thickness between about 10 nm and about 200 nm, and the intrinsic Ge₁₋ₓSnₓ layer has a thickness between about 0.1 μm and about 1 μm.

In a preferred embodiment of first aspect, the infrared detectors comprises a substrate comprising a n-doped Si surface layer; an intrinsic Ge₁₋ₓSnₓ layer formed directly over the n-doped Si surface layer; and a second p-doped Ge₁₋ₓSnₓ layer formed directly over the intrinsic Ge₁₋ₓSnₓ layer, wherein the intrinsic and second p-doped Ge₁₋ₓSnₓ layers each relaxed and each comprise a Ge₁₋ₓSnₓ alloy wherein x is about 0.01 to about 0.15, and wherein the second p-doped Ge₁₋ₓSnₓ layer has a thickness between about 10 nm and about 200 nm, and the intrinsic Ge₁₋ₓSnₓ layer has a thickness between about 0.1 μm and about 1 μm.

In a preferred embodiment of first aspect, the infrared detectors comprises a substrate comprising a Si surface layer, a first p-doped Ge₁₋ₓSnₓ layer formed directly over the Si surface layer; and a second n-doped Ge₁₋ₓSnₓ layer formed directly over the first p-doped Ge₁₋ₓSnₓ layer, provided that when the Si surface layer is doped, then the Si surface layer is p-doped, wherein the first and second Ge₁₋ₓSnₓ layers are each relaxed and each comprise a Ge₁₋ₓSnₓ alloy wherein x is about 0.01 to about 0.15, and wherein the first and second Ge₁₋ₓSnₓ layers each have a thickness between about 10 nm and about 200 nm.

In a preferred embodiment of first aspect, the infrared detectors comprises a substrate comprising a Si surface layer, a first n-doped Ge₁₋ₓSnₓ layer formed directly over the Si surface layer; and a second p-doped Ge₁₋ₓSnₓ layer formed directly over the first n-doped Ge₁₋ₓSnₓ layer, provided that when the Si surface layer is doped, then the Si surface layer is n-doped, wherein the first and second Ge₁₋ₓSnₓ layers are each relaxed and each comprise a Ge₁₋ₓSnₓ alloy wherein x is about 0.01 to about 0.15, and wherein the first and second Ge₁₋ₓSnₓ layers each have a thickness between about 10 nm and about 200 nm.

In a preferred embodiment of first aspect, the infrared detectors comprises a substrate comprising a p-doped Si surface layer, and a second n-doped Ge₁₋ₓSnₓ layer formed directly over the p-doped Si surface layer, wherein the second n-doped Ge₁₋ₓSnₓ layer is relaxed and comprises a Ge₁₋ₓSnₓ alloy wherein x is about 0.01 to about 0.15, and wherein the second n-doped Ge₁₋ₓSnₓ layer has a thickness between about 10 nm and about 200 nm.

In a preferred embodiment of first aspect, the infrared detectors comprises a substrate comprising a n-doped Si surface layer, and a second p-doped Ge₁₋ₓSnₓ layer formed directly over the n-doped Si surface layer, wherein the second p-doped Ge₁₋ₓSnₓ layer is relaxed and comprises a Ge₁₋ₓSnₓ alloy wherein x is about 0.01 to about 0.15, and wherein the second p-doped Ge₁₋ₓSnₓ layer has a thickness between about 10 nm and about 200 nm.

The preceding infrared detectors can further comprising an insulating layer formed over the second Ge₁₋ₓSnₓ layer. In one preferred embodiment, the insulating layer is SiO₂. Each infrared detector can further comprise at least one first electrode in electrical contact with the Si surface layer or the first Ge₁₋ₓSnₓ layer. When the at least one first electrode is in contact with the Si surface layer and the substrate is a Si wafer, then the electrode can either be in electrical contact via the front surface (the surface onto which the intrinsic Ge₁₋ₓSnₓ layer is formed) or the back face (the opposing face) of the wafer.

Further, each infrared detector can further comprise at least one second electrode in electrical contact with the second Ge₁₋ₓSnₓ layer. The first and second electrode can independently comprise Ti, Cr, Ni, Pd, Pt, Au, Ag, Al, Cu, or mixtures thereof. In one preferred embodiment, each electrode comprises an adhesion layer comprising Cr or Ti, and a contact layer comprising Pt, Au, Ag, Al, or Cu.

The infrared detector of the preceding embodiments can have an infrared photoresponse between about 1000 nm and about 4000 nm. In certain preferred embodiments, the infrared photoresponse between about 1000 nm and about 3500 nm; or about 1000 nm and about 3000 nm; or about 1000 nm and about 2500 nm; or about 1000 nm and about 2000 nm; or about 1000 nm and about 1900 nm; or about 1000 nm and about 1800 nm; or about 1000 nm and about 1750 nm.

Further, the infrared detector of the preceding embodiments can have an external quantum efficiency (EQE) in the L-telecommunication window of about 1×10⁻³ to about 3×10⁻². The various telecommunication windows are defined as follows:

| | |
|---|---|
| O band (original) | 1260 nm-1360 nm |
| E band (extended) | 1360 nm-1460 nm |
| S band (short wavelengths) | 1460 nm-1530 nm |
| C band [conventional (“erbium window”)] | 1530 nm-1565 nm |
| L band (long wavelengths) | 1565 nm-1625 nm |
| U band (ultralong wavelengths) | 1625 nm-1675 nm |

In certain preferred embodiments, the external quantum efficiency in the L-telecommunication window can be about 1×10⁻³ to about 2.5×10⁻²; or about 1×10⁻³ to about 2×10⁻²; or about 1×10⁻³ to about 1×10⁻²; or about 1×10⁻³ to about 7.5×10⁻³; or about 1×10⁻³ to about 5.0×10⁻³; or about 1×10⁻³ to about 4.0×10⁻³. Each of the preceding EQEs can be under a bias of about 0.10 V to about 0.20 V.

Further, the infrared detector of the preceding embodiment can have an external quantum efficiency in the U-telecommunication window of about 1×10⁻³ to about 3×10⁻². In certain preferred embodiments, the an external quantum efficiency in the L-telecommunication window can be about 1×10⁻³ to about 2.5×10⁻²; or about 1×10⁻³ to about 2×10⁻²; or about 1×10⁻³ to about 1×10⁻²; or about 1×10⁻³ to about 7.5×10⁻³; or about 1×10⁻³ to about 5.0×10⁻³; or about 1×10⁻³ to about 4.0×10⁻³; or about 1×10⁻³ to about 3.5×10⁻³; or about 1×10⁻³ to about 3.0×10⁻³. Each of the preceding EQEs can be under a bias of about 0.10 V to about 0.20 V.

In another preferred embodiment, the infrared detector can have an external quantum efficiency (EQE) in the L-telecommunication window of about 1×10⁻³ to about 1×10⁻² and an external quantum efficiency in the U-telecommunication window of about 1×10⁻³ to about 1×10⁻². In another preferred embodiment, the infrared detector can have an external quantum efficiency (EQE) in the L-telecommunication window of about 1×10⁻³ to about 1×10⁻²; and an external quantum efficiency in the U-telecommunication window of about 1×10⁻³ to about 5×10⁻³. In another preferred embodiment, the infrared detector can have an external quantum efficiency (EQE) in the L-telecommunication window of about 1×10⁻³ to about 5×10⁻³; and an external quantum efficiency in the U-telecommunication window of about 1×10⁻³ to about 5×10⁻³. In another preferred embodiment, the infrared detector can have an external quantum efficiency (EQE) in the L-telecommunication window of about 1×10⁻³ to about 5×10⁻³; and an external quantum efficiency in the U-telecommunication window of about 1×10⁻³ to about 3×10⁻³. Each of the preceding EQEs can be under a bias of about 0.10 V to about 0.20 V.

The infrared detectors any of the preceding embodiments may further comprise one or more light trapping features such as, but not limited to, texture and/or a surface reflector.

In a second aspect, the invention provides avalanche photodetectors comprising an infrared detector according to the first aspect or any embodiment thereof. The avalanche photodetectors can further comprise a multiplication layer disposed between the Si surface layer and the first Ge₁₋ₓSnₓ layer, when present, or the intrinsic Ge₁₋ₓSnₓ layer, when present; or disposed over the second Ge₁₋ₓSnₓ layer. Further, an optional charge layer can contact the multiplication layer and can be disposed between the multiplication layer and a Ge₁₋ₓSnₓ layer that it contacts. The multiplication layer can receive the primary charge carriers from one of the Ge₁₋ₓSnₓ layers and responsively produces the secondary charge carriers. The charge layer can act to keep the electric field in the multiplication layer high, while keeping the electric field in the GeSn layers low. Further, an electrical bias source can apply a bias voltage across the avalanche photodetectors structure.

In a third aspect, the invention provides photonic circuit elements comprising a infrared detector according to any embodiment of the first aspect, and a waveguiding structure in optical communication with the infrared detector. Such waveguiding structure may be in communication with a light emitting diode. The waveguiding structure can be formed, for example by a SiOₓN_{y} or Si₃N₄ layer between two SiO₂ cladding layers, where one of the SiO₂ cladding layers is in contact with the preceding insulating layer or both of the SiO₂ cladding layers forms part of the preceding insulating layer. See, for example, Yamada et al., Thin Solid Films 2006, 508, 399-401, which is hereby incorporated by reference in its entirety.

In a fourth aspect, the invention provides detector arrays comprising a plurality of infrared detector elements according the first aspect and any of the preceding embodiments thereof in a predetermined arrangement. For example, the infrared detector elements can be arranged in a 2-D grid. In another example, the infrared detector elements can be arranged in a line.

In one preferred embodiment, the detector arrays comprise a plurality of p-i-n infrared detector elements according the first aspect (i.e., comprising the intrinsic GeSn layer) and any of the preceding embodiments thereof in a predetermined arrangement.

In another preferred embodiment, the detector arrays comprise a plurality of p-n infrared detector elements according the first aspect (i.e., comprising no intrinsic GeSn layer) and any of the preceding embodiments thereof in a predetermined arrangement.

In general, such arrays can be formed across a substrate as described below. An array of detectors can be fabricated on a single substrate wafer. To form, for example, a focal-plane array, one could design the detectors appropriately (size, spacing, electrical connections, as is known to one skilled in the art), process the entire wafer, and then separate the arrays by cleaving, dicing, or sawing of the wafer, as is known in the art, to separate the individual arrays.

In a fifth aspect, the invention provides methods for fabricating infrared detectors comprising providing a substrate comprising a Si surface layer; optionally forming a first doped Ge₁₋ₓSnₓ layer over the Si surface layer; optionally forming an intrinsic Ge₁₋ₓSnₓ layer over the Si surface layer or, when present, the first doped Ge₁₋ₓSnₓ layer; and forming a second doped Ge₁₋ₓSnₓ layer over the intrinsic Ge₁₋ₓSnₓ layer, when present, or the first doped Ge₁₋ₓSnₓ layer, when present, or the Si surface layer; wherein one of (i) the Si surface layer or the first doped Ge₁₋ₓSnₓ layer and (ii) the second doped Ge₁₋ₓSnₓ layer is p-doped and the other of (i) and (ii) is n-doped, provided that when the Si surface layer is doped and the first doped Ge₁₋ₓSnₓ layer is present, then the Si surface layer and the first doped Ge₁₋ₓSnₓ layer are both n-doped or are both p-doped.

In one preferred embodiment, the methods comprise providing a substrate comprising a Si surface layer; optionally forming a first doped Ge₁₋ₓSnₓ layer over the Si surface layer; forming an intrinsic Ge₁₋ₓSnₓ layer over the Si surface layer or, when present, the first doped Ge₁₋ₓSnₓ layer; and forming a second doped Ge₁₋ₓSnₓ layer over the intrinsic Ge₁₋ₓSnₓ layer, wherein one of (i) the Si surface layer or the first doped Ge₁₋ₓSnₓ layer and (ii) the second doped Ge₁₋ₓSnₓ layer is p-doped and the other of (i) and (ii) is n-doped, provided that when the Si surface layer is doped and the first doped Ge₁₋ₓSnₓ layer is present, then the Si surface layer and the first doped Ge₁₋ₓSnₓ layer are both n-doped or are both p-doped.

In one preferred embodiment, the methods comprise providing a substrate comprising a Si surface layer; forming a first doped Ge₁₋ₓSnₓ layer over the Si surface layer; forming an intrinsic Ge₁₋ₓSnₓ layer over the first doped Ge₁₋ₓSnₓ layer; and forming a second doped Ge₁₋ₓSnₓ layer over the intrinsic Ge₁₋ₓSnₓ layer, wherein one of (i) the first doped Ge₁₋ₓSnₓ layer and (ii) the second doped Ge₁₋ₓSnₓ layer is p-doped and the other of (i) and (ii) is n-doped, provided that when the Si surface layer is doped, then the Si surface layer and the first doped Ge₁₋ₓSnₓ layer are both n-doped or are both p-doped.

In one preferred embodiment, the methods comprise providing a substrate comprising a Si surface layer; forming a first p-doped Ge₁₋ₓSnₓ layer over the Si surface layer; forming an intrinsic Ge₁₋ₓSnₓ layer over the first p-doped Ge₁₋ₓSnₓ layer; and forming a second n-doped Ge₁₋ₓSnₓ layer over the intrinsic Ge₁₋ₓSnₓ layer, provided that when the Si surface layer is doped, then the Si surface layer is p-doped.

In one preferred embodiment, the methods comprise providing a substrate comprising a p-doped Si surface layer; forming a first p-doped Ge₁₋ₓSnₓ layer over the Si surface layer; forming an intrinsic Ge₁₋ₓSnₓ layer over the first p-doped Ge₁₋ₓSnₓ layer; and forming a second n-doped Ge₁₋ₓSnₓ layer over the intrinsic Ge₁₋ₓSnₓ layer.

In one preferred embodiment, the methods comprise providing a substrate comprising a Si surface layer; forming a first n-doped Ge₁₋ₓSnₓ layer over the Si surface layer; forming an intrinsic Ge₁₋ₓSnₓ layer over the first n-doped Ge₁₋ₓSnₓ layer; and forming a second p-doped Ge₁₋ₓSnₓ layer over the intrinsic Ge₁₋ₓSnₓ layer, provided that when the Si surface layer is doped, then the Si surface layer is n-doped.

In one preferred embodiment, the methods comprise providing a substrate comprising a n-doped Si surface layer; forming a first n-doped Ge₁₋ₓSnₓ layer over the Si surface layer; forming an intrinsic Ge₁₋ₓSnₓ layer over the first n-doped Ge₁₋ₓSnₓ layer; and forming a second p-doped Ge₁₋ₓSnₓ layer over the intrinsic Ge₁₋ₓSnₓ layer.

In one preferred embodiment, the methods comprise providing a substrate comprising a doped Si surface layer; forming an intrinsic Ge₁₋ₓSnₓ layer over the doped Si surface layer; and forming a second doped Ge₁₋ₓSnₓ layer over the intrinsic Ge₁₋ₓSnₓ layer, wherein one of (i) the Si surface layer or and (ii) the second doped Ge₁₋ₓSnₓ layer is p-doped and the other of (i) and (ii) is n-doped.

In one preferred embodiment, the methods comprise providing a substrate comprising a p-doped Si surface layer; forming an intrinsic Ge₁₋ₓSnₓ layer over the doped Si surface layer; and forming a second n-doped Ge₁₋ₓSnₓ layer over the intrinsic Ge₁₋ₓSnₓ layer.

In one preferred embodiment, the methods comprise providing a substrate comprising a n-doped Si surface layer; forming an intrinsic Ge₁₋ₓSnₓ layer over the doped Si surface layer; and forming a second p-doped Ge₁₋ₓSnₓ layer over the intrinsic Ge₁₋ₓSnₓ layer.

In another preferred embodiment, the methods comprise providing a substrate comprising a Si surface layer; optionally forming a first doped Ge₁₋ₓSnₓ layer over the Si surface layer; forming a second doped Ge₁₋ₓSnₓ layer over the first doped Ge₁₋ₓSnₓ layer, when present, or the Si surface layer; wherein one of (i) the Si surface layer or the first doped Ge₁₋ₓSnₓ layer and (ii) the second doped Ge₁₋ₓSnₓ layer is p-doped and the other of (i) and (ii) is n-doped, provided that when the Si surface layer is doped and the first doped Ge₁₋ₓSnₓ layer is present, then the Si surface layer and the first doped Ge₁₋ₓSnₓ layer are both n-doped or are both p-doped.

In another preferred embodiment, the methods comprise providing a substrate comprising a Si surface layer; forming a first doped Ge₁₋ₓSnₓ layer over the Si surface layer; and forming a second doped Ge₁₋ₓSnₓ layer over the first doped Ge₁₋ₓSnₓ layer; wherein one of (i) the first doped Ge₁₋ₓSnₓ layer and (ii) the second doped Ge₁₋ₓSnₓ layer is p-doped and the other of (i) and (ii) is n-doped, provided that when the Si surface layer is doped, then the Si surface layer and the first doped Ge₁₋ₓSnₓ layer are both n-doped or are both p-doped.

In another preferred embodiment, the methods comprise providing a substrate comprising a Si surface layer; forming a first p-doped Ge₁₋ₓSnₓ layer over the Si surface layer; and forming a second n-doped Ge₁₋ₓSnₓ layer over the first p-doped Ge₁₋ₓSnₓ layer; provided that when the Si surface layer is doped, then the Si surface layer is p-doped.

In another preferred embodiment, the methods comprise providing a substrate comprising a Si surface layer; forming a first n-doped Ge₁₋ₓSnₓ layer over the Si surface layer; and forming a second p-doped Ge₁₋ₓSnₓ layer over the first n-doped Ge₁₋ₓSnₓ layer; provided that when the Si surface layer is doped, then the Si surface layer is n-doped.

In another preferred embodiment, the methods comprise providing a substrate comprising a doped Si surface layer; and forming a second doped Ge₁₋ₓSnₓ layer over the doped Si surface layer; wherein one of the Si surface layer and the second doped Ge₁₋ₓSnₓ layer is p-doped and the other is n-doped.

In another preferred embodiment, the methods comprise providing a substrate comprising a n-doped Si surface layer; and forming a second p-doped Ge₁₋ₓSnₓ layer over the n-doped Si surface layer.

In another preferred embodiment, the methods comprise providing a substrate comprising a p-doped Si surface layer; and forming a second n-doped Ge₁₋ₓSnₓ layer over the p-doped Si surface layer.

Methods for preparing the various Ge₁₋ₓSnₓ layers can be found, for example, in U.S. Patent Application Publication No. US2007-0020891-A1, which is hereby incorporated by reference in its entirety.

n-Type Ge₁₋ₓSnₓ layers can be prepared by the controlled substitution of P, As, or Sb atoms in the Ge₁₋ₓSnₓ lattice according to methods known to those skilled in the art. One example includes, but is not limited to, the use of P(GeH₃)₃ or As(GeH₃)₃, which can furnish structurally and chemically compatible PGe₃ and AsGe₃ molecular cores, respectively (see, Chizmeshya et al., Chem. Mater. 2006, 18, 6266; and US Patent Application Publication No. 2006-0134895-A1, each of which are hereby incorporated by reference in their entirety) can give n-type Ge₁₋ₓSnₓ layers.

p-Type Ge₁₋ₓSnₓ layers can be prepared by the controlled substitution of B, Al, Ga, or In atoms in the Ge₁₋ₓSnₓ lattice according to methods known to those skilled in the art. One example includes, but is not limited to, conventional CVD reactions of SnD₄, Ge₂H₆ and B₂H₆ at low temperatures.

Forming the first doped Ge₁₋ₓSnₓ layer can comprise contacting the Si surface layer with a first vapor comprising Ge₂H₆, SnD₄, and a first dopant source under conditions suitable for depositing the first doped Ge₁₋ₓSnₓ layer. In preferred embodiments, the first vapor comprises about 0.1 wt. % to about 5 wt. % of the first dopant source.

In a preferred embodiment, the first vapor comprises about 0.5 wt. % to about 5 wt. % of the first dopant source. In other preferred embodiments, the first vapor comprises about 1.0 wt. % to about 5 wt. % of the first dopant source. In other preferred embodiments, the first vapor comprises about 0.5 wt. % to about 2 wt. % of the first dopant source. In other preferred embodiments, the first vapor comprises about 0.5 wt. % to about 1.5 wt. % of the first dopant source. In other preferred embodiments, the first vapor comprises about 1.0 wt. % of the first dopant source. Such doping methods can provide first doped Ge₁₋ₓSnₓ layer having carrier concentrations in the range of about 10¹⁷ cm⁻³ to about 10²² cm⁻³; or about 10¹⁸ cm⁻³ to about 10²² cm⁻³; or about 10¹⁷ cm⁻³ to about 10²¹ cm⁻³; or about 10¹⁸ cm⁻³ to about 10²¹ cm⁻³; or about 10¹⁷ cm⁻³ to about 10¹⁹ cm⁻³.

When the first doped Ge₁₋ₓSnₓ layer is n-doped, then the first dopant source can comprise of P(SiH₃)₃, As(SiH₃)₃, P(GeH₃)₃, As(GeH₃)₃, or mixtures thereof. In one preferred embodiment, the first dopant source comprises P(GeH₃)₃ or As(GeH₃)₃. In another preferred embodiment, the first dopant source comprises P(GeH₃)₃. In another preferred embodiment, the first dopant source comprises As(GeH₃)₃.

When the first doped Ge₁₋ₓSnₓ layer is p-doped, then the first dopant source can comprise of B₂H₆ or AlH₃ (Al₂H₆). In another preferred embodiment, the first dopant source comprises B₂H₆.

In a further preferred embodiment, the first vapor is introduced at a temperature between about 250° C. and about 400° C., or about 300° C. and about 400° C., more preferably between about 325° C. and about 375° C., and even more preferably between about 300° C. and about 350° C.

In various further preferred embodiments, the first vapor is introduced at a partial pressure a pressure between about 1 mTorr and about 1000 mTorr. In one preferred embodiment, the first vapor is introduced at a pressure between about 100 mTorr and about 1000 mTorr. In one preferred embodiment, the first vapor is introduced at a pressure between about 100 mTorr and about 500 mTorr. In one preferred embodiment, the first vapor is introduced at a pressure between about 200 mTorr and about 500 mTorr.

In certain preferred embodiments, the first vapor is introduced at a temperature between about 325° C. and about 375° C., and a pressure between about 1 mTorr and about 1000 mTorr. In certain preferred embodiments, the first vapor is introduced at a temperature between about 325° C. and about 375° C., and a pressure between about 100 mTorr and about 500 mTorr.

In certain preferred embodiments, the first vapor is introduced at a temperature between about 300° C. and about 350° C., and a pressure between about 1 mTorr and about 1000 mTorr. In certain preferred embodiments, the first vapor is introduced at a temperature between about 300° C. and about 350° C., and a pressure between about 100 mTorr and about 500 mTorr.

The intrinsic Ge₁₋ₓSnₓ layer can be formed by contacting the Si surface layer or the first doped Ge₁₋ₓSnₓ layer, when present, with a second vapor comprising Ge₂H₆ and SnD₄ under conditions suitable for depositing the intrinsic Ge₁₋ₓSnₓ layer.

In a further preferred embodiment, the second vapor is introduced at a temperature between about 250° C. and about 400° C., or about 300° C. and about 400° C., more preferably between about 325° C. and about 375° C., and even more preferably between about 300° C. and about 350° C.

In various further preferred embodiments, the second vapor is introduced at a partial pressure between 1 mTorr and about 1000 mTorr. In one preferred embodiment, the second vapor is introduced at a pressure between about 100 mTorr and about 1000 mTorr. In one preferred embodiment, the second vapor is introduced at a pressure between about 100 mTorr and about 500 mTorr. In one preferred embodiment, the second vapor is introduced at a pressure between about 200 mTorr and about 500 mTorr.

In certain preferred embodiments, the second vapor is introduced at a temperature between about 325° C. and about 375° C., and a pressure between about 1 mTorr and about 1000 mTorr. In certain preferred embodiments, the second vapor is introduced at a temperature between about 325° C. and about 375° C., and a pressure between about 100 mTorr and about 500 mTorr.

In certain preferred embodiments, the second vapor is introduced at a temperature between about 300° C. and about 350° C., and a pressure between about 1 mTorr and about 1000 mTorr. In certain preferred embodiments, the second vapor is introduced at a temperature between about 300° C. and about 350° C., and a pressure between about 100 mTorr and about 500 mTorr.

Forming the second doped Ge₁₋ₓSnₓ layer can comprise contacting the intrinsic Ge₁₋ₓSnₓ layer, when present, or the first Ge₁₋ₓSnₓ layer, when present, or the Si surface layer, with a third vapor comprising Ge₂H₆, SnD₄, and a second dopant source under conditions suitable for depositing the second doped Ge₁₋ₓSnₓ layer. In preferred embodiments, the third vapor comprises about 0.1 wt. % to about 5 wt. % of the second dopant source. In other preferred embodiments, the third vapor comprises about 0.5 wt. % to about 5 wt. % of the second dopant source. In other preferred embodiments, the third vapor comprises about 1.0 wt. % to about 5 wt. % of the second dopant source. In other preferred embodiments, the third vapor comprises about 0.5 wt. % to about 2 wt. % of the second dopant source. In other preferred embodiments, the third vapor comprises about 0.5 wt. % to about 1.5 wt. % of the second dopant source. In other preferred embodiments, the third vapor comprises about 1.0 wt. % of the second dopant source. Such doping methods can provide second doped Ge₁₋ₓSnₓ layer having carrier concentrations in the range of about 10¹⁷ cm⁻³ to about 10²² cm⁻³; or about 10¹⁸ cm⁻³ to about 10²² cm⁻³; or about 10¹⁷ cm⁻³ to about 10²¹ cm⁻³; or about 10¹⁸ cm⁻³ to about 10²¹ cm⁻³; or about 10¹⁷ cm⁻³ to about 10¹⁹ cm⁻³.

When the second doped Ge₁₋ₓSnₓ layer is n-doped, then the second dopant source can comprise of P(SiH₃)₃, As(SiH₃)₃, P(GeH₃)₃, As(GeH₃)₃, or mixtures thereof. In one preferred embodiment, the second dopant source comprises P(GeH₃)₃ or As(GeH₃)₃. In another preferred embodiment, the second dopant source comprises P(GeH₃)₃. In another preferred embodiment, the second dopant source comprises As(GeH₃)₃.

When the second doped Ge₁₋ₓSnₓ layer is p-doped, then the second dopant source can comprise of B₂H₆ or AlH₃ (Al₂H₆). In another preferred embodiment, the second dopant source comprises B₂H₆.

In a further preferred embodiment, the third vapor is introduced at a temperature between about 250° C. and about 400° C., or about 300° C. and about 400° C., more preferably between about 325° C. and about 375° C., and even more preferably between about 300° C. and about 350° C.

In various further preferred embodiments, the third vapor is introduced at a partial pressure between about 1 mTorr and about 1000 mTorr. In one preferred embodiment, the third vapor is introduced at a pressure between about 100 mTorr and about 1000 mTorr. In one preferred embodiment, the third vapor is introduced a pressure at between about 100 mTorr and about 500 mTorr. In one preferred embodiment, the third vapor is introduced at a pressure between about 200 mTorr and about 500 mTorr.

In certain preferred embodiments, the third vapor is introduced at a temperature between about 325° C. and about 375° C., and a pressure between about 1 mTorr and about 1000 mTorr. In certain preferred embodiments, the third vapor is introduced at a temperature between about 325° C. and about 375° C., and a pressure between about 100 mTorr and about 500 mTorr.

In certain preferred embodiments, the third vapor is introduced at a temperature between about 300° C. and about 350° C., and a pressure between about 1 mTorr and about 1000 mTorr. In certain preferred embodiments, the third vapor is introduced at a temperature between about 300° C. and about 350° C., and a pressure between about 100 mTorr and about 500 mTorr.

In one preferred embodiment, each of the first vapor, when the first doped Ge₁₋ₓSnₓ layer is formed, and the second and third vapors are introduced at a temperature between about 300° C. and about 350° C., and a pressure between about 100 mTorr and about 500 mTorr.

In one preferred embodiment, each of the first vapor, when the first doped Ge₁₋ₓSnₓ layer is formed, and the second and third vapors are introduced at a temperature between about 300° C. and about 350° C., and a pressure between about 100 mTorr and about 500 mTorr, where the first dopant source comprises B₂H₆ and the second dopant source comprises P(GeH₃)₃ or As(GeH₃)₃. In another preferred embodiment, each of the first vapor, when the first doped Ge₁₋ₓSnₓ layer is formed, and the second and third vapors are introduced at a temperature between about 300° C. and about 350° C., and a pressure between about 100 mTorr and about 500 mTorr, where the first dopant source comprises B₂H₆ and the second dopant source comprises P(GeH₃)₃. In another preferred embodiment, each of the first vapor, when the first doped Ge₁₋ₓSnₓ layer is formed, and the second and third vapors are introduced at a temperature between about 300° C. and about 350° C., and a pressure between about 100 mTorr and about 500 mTorr, where the first dopant source comprises B₂H₆ and the second dopant source comprises As(GeH₃)₃.

In another preferred embodiment, each of the first vapor, when the first doped Ge₁₋ₓSnₓ layer is formed, and the second and third vapors are introduced at a temperature between about 300° C. and about 350° C., and a pressure between about 100 mTorr and about 500 mTorr, where the first dopant source comprises P(GeH₃)₃ or As(GeH₃)₃ and the second dopant source comprises B₂H₆.

After growth of each desired Ge₁₋ₓSnₓ layer, such can be subject to a post-growth Rapid Thermal Annealing treatment. For example, the structure can be heated to a temperature of about 750° C. and held at such temperature for about 1 second to about 10 seconds. The structure can be cycled multiple times between the temperature utilized for GeSn deposition (about 300° C. to about 350° C.) to about 750° C. For example, the structure can be cycled from 1 to 10 times, or 1 to 5 times, or 1 to 3 times. In one preferred embodiment, the first doped Ge₁₋ₓSnₓ layer is rapid thermal annealed to a temperature between about 300° C. and about 750° C. at least two times. In one preferred embodiment, the second doped Ge₁₋ₓSnₓ layer is rapid thermal annealed to a temperature between about 300° C. and about 750° C. at least two times. In another preferred embodiment, the first and second doped Ge₁₋ₓSnₓ layers are rapid thermal annealed to a temperature between about 300° C. and about 750° C. at least two times.

In a further embodiment, any of the preceding embodiment can further comprise forming an insulating layer, for example, SiO₂, over the second doped Ge₁₋ₓSnₓ layer. The insulating layer can have a thickness between about 10 nm to about 1000 nm. For example, the insulating layer can have a thickness between about 10 nm and about 900 nm, or about 10 nm and about 800 nm, or about 10 nm and about 700 nm, or about 10 nm and about 600 nm, or about 10 nm and about 500 nm, or about 10 nm and about 400 nm, or about 10 nm and about 300 nm, or about 10 nm and about 200 nm, or about 10 nm and about 100 nm. In other examples, the insulating layer can each have a thickness between about 25 nm and about 1000 nm, or about 50 nm and about 1000 nm, or about 75 nm and about 1000 nm, or about 100 nm and about 1000 nm, or about 100 nm and about 500 nm, or about 100 nm and about 300 nm, or about 100 nm and about 200 nm.

Standard lithography can be used employed to delineate the appropriate patterns thereon, for example, mesa patterns using a positive photoresist, such as, but not limited to, AZ 3312 photoresist.

Reactive ion etching (RIE) can then be used to create patterned mesas. For example, BCl₃ gas can be used as the reactant to generate plasma at flow rate of 8 sccm, pressure of 50 mTorr and RF power setting of 50 W, and an etch rate of 50 nm/min. Preferably, the mesas produced have well-defined shapes, sharp edges, and flat, residue-free sidewalls.

The photoresist can be removed as is familiar to one skilled in the art, for example, with acetone, and a SiO₂ layer can be deposited on top of the mesas, which serves as an antireflective and passivation coating. The SiO₂ layer can have a thickness between about 100 nm and about 1000 nm. For example, the SiO₂ layer thickness can be between about 200 nm and about 1000 nm, or about 200 nm and about 750 nm, or about 300 nm and about 750 nm, or about 300 nm and about 600 nm, or about 400 nm and about 600 nm, or about 400 nm and 500 nm.

In certain preferred embodiments, the methods comprise forming at least one first electrode in electrical contact with the Si surface layer. In certain preferred embodiments, the methods comprise forming at least one second electrode in electrical contact with the second doped Ge₁₋ₓSnₓ layer. Such contacts can be formed either on the front side of the devices or the back side.

For example, metal contact (electrode) areas can be defined via a lift-off process (e.g., etching and filling) as is familiar to one skilled in the art, for example, by using a negative photoresist such as, but not limited to, AZ 4330 photoresist, which is suitable for this purpose due to the negative profile of the sidewall. In such instances, when first doped Ge₁₋ₓSnₓ layer is present, the first doped layer should be thick enough to stop the etching process within the layer to provide contact. Such thickness can be determined by one skilled in the art.

Metal contacts (e.g., the first and/or second electrodes) can be deposited, using e-beam evaporation, consisting of an adhesion layer followed by a metal film. The first and second electrode can independently comprise Ti, Cr, Ni, Pd, Pt, Au, Ag, Al, Cu, or mixtures thereof. Suitable adhesion layers include, but are not limited to Cr or Ti. Metal films include, but are not limited to Pt, Au, Ag, Al, or Cu. After metal lift-off, the samples can be cleaned in an oxygen plasma.

In the third aspect, the gaseous precursors (first, second, and third vapors) for deposition of the various Ge₁₋ₓSnₓ layers can be deposited by any suitable technique, including but not limited to gas source molecular beam epitaxy, chemical vapor deposition, plasma enhanced chemical vapor deposition, laser assisted chemical vapor deposition, and atomic layer deposition. In one embodiment, each of the Ge₁₋ₓSnₓ layers can be formed by chemical vapor deposition or molecular beam epitaxy.

In certain preferred embodiments, the first doped Ge₁₋ₓSnₓ layer, when present, the second doped Ge₁₋ₓSnₓ layer and the intrinsic Ge₁₋ₓSnₓ layer are each independently formed by molecular beam epitaxy or chemical vapor deposition.

In certain preferred embodiments, the doping of the first doped Ge₁₋ₓSnₓ layer and the second doped Ge₁₋ₓSnₓ layer are not provided by ion implantation.

The methods of the fifth aspect can be used for preparing the infrared detectors according to the first aspect of the invention, the avalanche detectors of the second aspect, the photonic circuit elements of the third aspect, the arrays according to the fourth aspect, and any embodiments thereof.

### EXAMPLES

### Example 1

### Optoelectronic Ge_{1-y}Sn_{y} Alloys

From a fundamental view point Ge_{1-y}Sn_{y} alloys on their own right are intriguing IR materials that undergo an indirect-to-direct band gap transition with variation of their strain state and/or compositions. They also serve as versatile, compliant buffers for the growth of II-VI and III-V compounds on Si substrates.

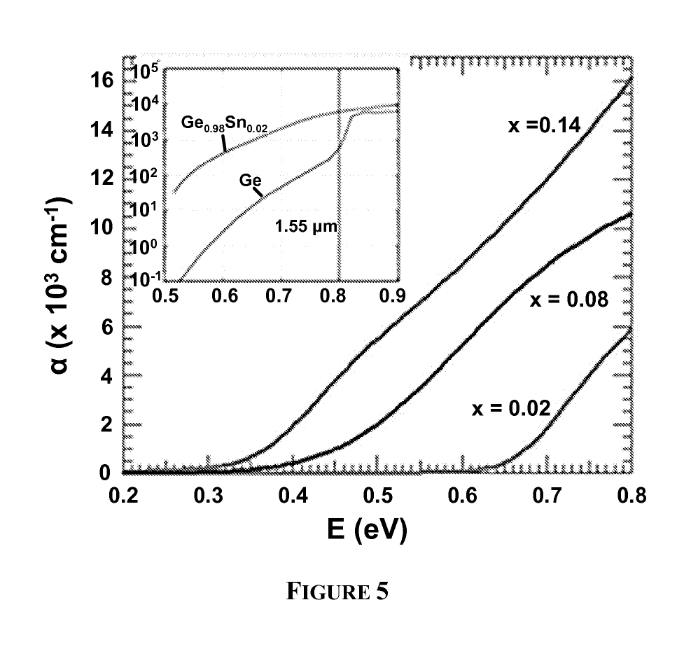

The fabrication of the Ge_{1-y}Sn_{y} materials directly on Si wafers has recently been reported using a specially developed CVD method involving reactions of Ge₂H₆ with SnD₄ in high purity H₂ (10%). Thick and atomically flat films are grown at about 250 to about 350° C. and possess low densities of threading dislocations (˜10⁵ cm⁻²) and high concentrations of Sn atoms up to about 20%. Since the incorporation of Sn lowers the absorption edges of Ge, the Ge_{1-y}Sn_{y} alloys are attractive for detector applications that require band gaps lower than that of Ge (0.80 eV). The absorption coefficient of selected Ge₁₋ₓSnₓ samples, showing high absorption well below the Ge band gap, is show in FIG. 5 (see, D'Costa et al., Phys. Rev. B 2006, 73, 125207).

The compositional dependence of the Ge_{1-y}Sn_{y} band structure shows a dramatic reduction of the Ge-like optical transitions (the direct gap E₀, the split-off E₀+Δ₀ gap, and the higher-energy E₁, E₁+Δ₁, E_{0′} and E₂ critical points) as a function of Sn concentration (see, D'Costa, supra). With only 15 at. % Sn, the E₀ gap is reduced by half relative to that of pure Ge (0.80 eV). The concomitant lowering of the absorption edge implies that the relevant photodetector wavelengths can be covered with modest amounts of Sn in the alloys. Recent electrical measurements on prototype devices based on these materials are encouraging. Hall and IR ellipsometry indicate that the as-grown material is p-type, with hole concentrations in the 10¹⁶ cm⁻³ range. This background doping is found to be due to defects in the material and can be reduced using rapid thermal annealing. This occurs with a simultaneous increase in mobility to values above 600 cm²/V-sec, suggesting that the thermal treatment is truly removing the acceptor defects rather than creating compensating donor defects.

n-Type Ge₁₋ₓSnₓ layers can be prepared by the controlled substitution of active As atoms in the lattice is made possible by the use of As(GeH₃)₃, which furnishes structurally and chemically compatible AsGe₃ molecular cores (as described above). p-Type Ge₁₋ₓSnₓ layers can be prepared via conventional CVD reactions of SnD₄, Ge₂H₆ and B₂H₆ at low temperatures. Electrical measurements indicate that high carrier concentrations (˜3×10¹⁹ atoms/cm³) can be routinely achieved via these methods.

### Example 2

### Fabrication of Ge₁₋ₓSnₓ Infrared Detector

Ge_{0.98}Sn_{0.02} active material was grown on boron-doped (p-type) Si(100) with resistivity 0.01 Ωcm. Prior to growth, the wafers were chemically cleaned by a modified RCA process and then dipped in 5% HF solution to hydrogen-passivate their surface. The UHV-CVD growth of the intrinsic Ge_{0.98}Sn_{0.02} was conducted by reactions of digermane Ge₂H₆ and deuterated stannane SnD₄ at 350° C. and 300 mTorr, yielding an average growth rate of about 10 nm/min. A post growth annealing step, consisting of 3 cycles at 750° C. for 2 seconds, was used to reduce the levels of threading defects and ensure that the material is devoid of any residual strains. The wafers were then loaded back into the growth chamber to conduct the deposition of the n-type capping layer using a 1% admixture P(GeH₃)₃ as the source of the P atoms. This compound and related families of single source dopants [(P,As)(MH₃)₃, M=Si,Ge] are the key enabling ingredient for low-temperature doping of the Ge—Sn based materials en route to high performance devices. The precursors are stable, volatile and contain preformed M-(P,As) near-tetrahedral bonding arrangements, which are incorporated intact into the host structure to yield a homogeneous distribution of substitutional dopant without clustering or segregation, ensuring full activation at the levels in the 10¹⁸ cm⁻³ to 10²⁰ cm⁻³ range. In contrast to conventional high temperature/energy methods, this soft chemistry strategy also mitigates structural and morphological imperfections which ultimately degrade device performance.

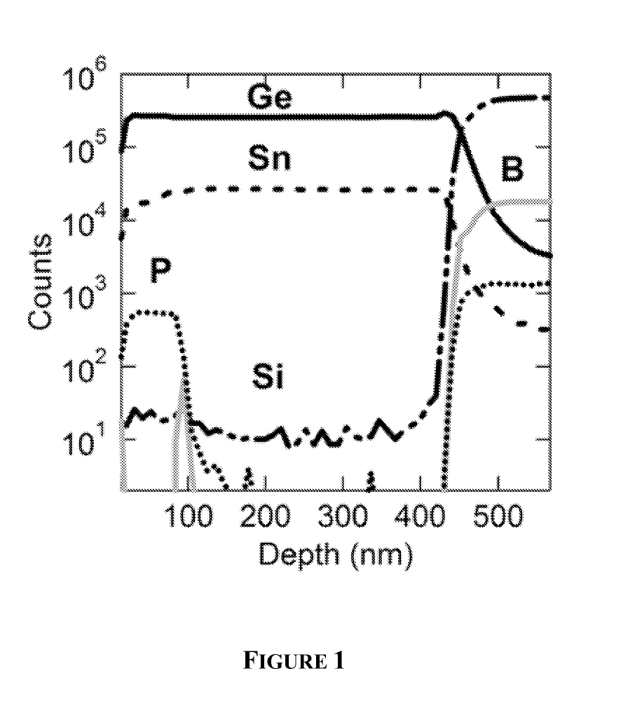

The growth conditions employed in the doping step were the same as those used for the formation of the intrinsic material, yielding n-doped Ge_{0.98}Sn_{0.02} films with a thickness 64 nm and active carrier concentrations of 7.5×10¹⁹ cm⁻³, as determined by spectroscopic ellipsometry. The samples were subsequently characterized for composition, structure and crystallinity by XRD, RBS and SIMS. Reciprocal space maps of the (224) reflection and on-axis (004) plots confirmed that the annealed layers are fully relaxed. The FWHM of the (004) rocking curve was measured to be 0.275°, which indicates the presence of a minor crystal mosaicity and occasional threading dislocations in the epilayer. RBS was used to show that the Sn content in both the intrinsic and P doped layers of the heterostructure was identical at 2%. SIMS depth profiles (FIG. 1) showed a sharp transition between the top P-doped film and the underlying intrinsic layer. The phosphorus atom distribution was found to be uniform throughout the n-type layer with a nominal concentration of 1×10²⁰ cm⁻³, in agreement with the ellipsometric measurements. The corresponding B concentration in Si substrate was found to be 4.3×10¹⁹ cm⁻³, as expected. The elemental profile of the intrinsic layer showed B and P impurity levels well below the detection limit.

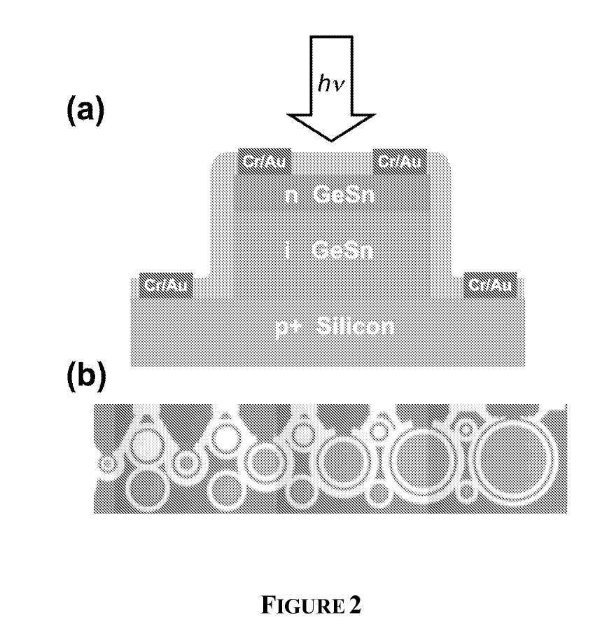

The fabrication process started with cleaning of the GeSn film by sonication in methanol. An insulating SiO₂ blanket layer with thickness of 150 nm was then deposited using PECVD to passivate and protect the surface of the film. Standard lithography was employed to delineate the mesa patterns (FIG. 2) using the AZ3312 photoresist. Reactive ion etching (RIE) was then used to create circular mesas using BCl₃ gas as the reactant to generate plasma at flow rate of 8 sccm, pressure of 50 mTorr and RF power setting of 50 W. Under these conditions an etch rate of 50 nm/min produces mesas with well-defined shapes, sharp edges, and flat, residue-free sidewalls. After etching the photoresist was removed with acetone and a 420 nm thick SiO₂ layer was deposited on top of the mesas, which served as an antireflective and passivation coating. The metal contact areas were defined via a lift-off process using the AZ4330 photoresist, which is suitable for this purpose due to the negative profile of the sidewall. The metal stack, consisting of a 20 nm Cr adhesion layer followed by a 200 nm thick Au film, was deposited on the patterned samples using e-beam evaporation at pressures p=3×10⁻⁶ Torr. Other metal combinations produced higher contact resistance. After metal lift-off in acetone, the samples were cleaned in an oxygen plasma and visually inspected by optical microscopy to ensure the cleanliness and geometric perfection of the desired features.

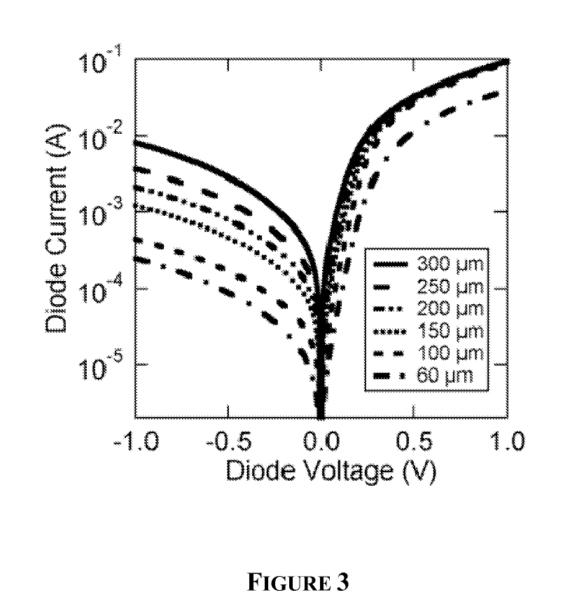

Using the above procedures, circular devices with diameters ranging from 60 to 300 microns were fabricated on a single wafer to facilitate systematic testing. In FIG. 3 we show the dark I-V plots for the entire set. For a 60 μm-diameter device, with currents of 0.38 mA and 32 mA at −1V and 1V, respectively, the “turn-on” voltage is found to be 0.19 V, which is similar to the value obtained in pure Ge p-i-n diodes (see, K. Leaver, Microelectronic Devices (Imperial College Press, London, 2003)). The corresponding I-V plot was used to extract an ideality factor n=1.52. The breakdown voltage was determined to be −5.5V, nearly seven times larger than the material bandgap (0.72 eV), indicating that the observed diode “breakdown” is most likely caused by an avalanche mechanism (see, S. M. Sze, Physics of Semiconductor Devices (Wiley, New York, 1981)). Our measured dark current densities near 1 A/cm² can be compared with dark current densities of approximately 10⁻²/10⁻³ A/cm⁻² reported by several authors in Ge/Si heterostructure diodes (see, Colace, L. et al., J. Lumin. 121, 413 (2006); Colace, L. et al., Photonics Technology Letters, IEEE 19, 1813 (2007); and Luan, H. C. et al., Optical Materials 17, 71 (2001)). The latter, however, are observed in much thicker (micron) and larger area (mm size) devices, while our results were obtained from 350 nm-thick films with micrometer-size areas. Most recently, Osmond and coworkers achieved a record low 10⁻⁶ A/cm⁻² value in 1 Ge devices with 3 mm diameter grown by low-energy plasma-enhanced CVD (see, Osmond, J. et al., Appl. Phys. Lett. 94, 201106 (2009)). Based on the lower band gap of Ge_{0.98}Sn_{0.02}, the dark current would not be expected to increase more than one order of magnitude relative to Ge. The excess dark currents measured in our devices are consistent with the intermediate value found for the diode ideality factor, which suggests a significant contribution from the generation current. In the case of Ge on Si detectors, it has been shown that the annealing step is critical for the reduction of the dark currents, and significant work has been devoted over the course of the past decade to optimize this process. In our case, for this first generation GeSn devices, we use the FWHM of the (004) X-ray reflection in the intrinsic layer as a figure of merit for the optimization associated with the annealing step. We expect that by using the dark current itself as the figure of merit the annealing protocol and the device geometry can be substantially optimized to yield much lower dark currents. As the photodiode design evolves, additional improvements are expected by increasing the active layer thickness beyond the current 350 nm value which limits the effective volume (defect-free region) above the interface. The dark current has also been shown to depend on the doping levels in the diode (see, Masini, C. et al., Electron Devices, IEEE Transactions on 48, 1092 (2001)), and further reductions could be expected from an optimization for the Si/GeSn heterostructure.

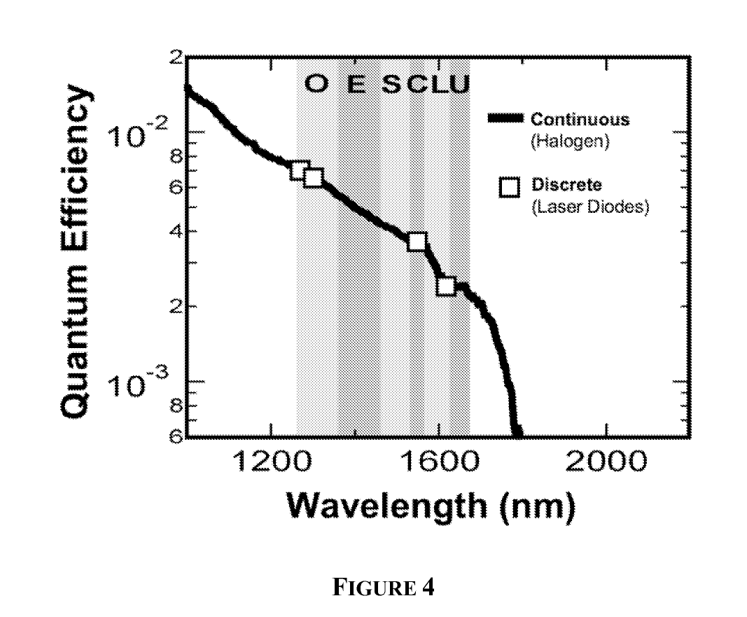

The photoresponse of the devices was measured as a photocurrent upon illumination of the diodes by monochromatized light generated by a halogen lamp and delivered to the capping SiO₂ window of the photodiode using an optical fiber. We found that with increasing bias the highest device response is obtained at 0.16 V for all mesa sizes. The spectral dependence of the external quantum efficiency (EQE) obtained from a typical 300 μm device at this bias setting is plotted in FIG. 4. We see a substantial response at all optical communication wavelengths (O-U bands). We note that the GeSn EQE at 1620 nm is lower by 20% relative to that at λ=1550 nm. In contrast, the EQE decreases rapidly beyond 1550 nm in pure Ge diodes. At λ=1620 nm the EQE is only 10% of its 1550 nm value, and at the photoresponse is negligible at 1700 nm and beyond (see, Osmond, J. et al., Appl. Phys. Lett. 94, 201106 (2009)). The dramatic difference between the two types of devices reflects the lower direct band gap of Ge_{0.98}Sn_{0.02} (E₀=0.72 eV) as opposed to Ge (E₀=0.80 eV). Notice that the direct-indirect transition is not as sharp as in the case of pure Ge as a result of alloy broadening. At 1300 nm the EQE of our device at zero bias is 2.4×10⁻³, which is more than one order of magnitude higher than the EQE measured by Osmond et al (Osmond 2009, supra) in 1 μm thick Ge/Si p-i-n devices. This is associated with the much higher absorption coefficient of the Ge_{1-y}Sn_{y} alloys compared to that of Ge.

In summary, we have fabricated and characterized p-i-n detector structures incorporating Ge_{0.98}Sn_{0.02} active layers and have determined that the fabricated devices show a high infrared photoresponse down to 1750 nm. The results demonstrate that Ge_{1-y}Sn_{y} alloys represent a practical and potentially superior alternative to Ge for telecommunication applications. Increased Sn concentrations in the alloy are expected to shift the responsivity further into the infrared, overlapping the wavelength range of InGaAs detectors. From a growth and doping perspective, a critical advantage of our inherently low-temperature soft-chemistry approach is that all high-energy processing steps are completely circumvented.

### Example 3

### Fabrication of Ge₁₋ₓSnₓ Infrared Detector

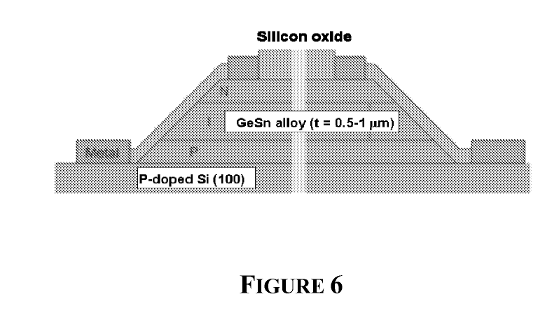

A infrared detector was fabricated as illustrated in cross-section in FIG. 6 comprising Ge₁₋ₓSnₓ pin regions on a p-doped Si substrate. The preliminary test results indicated that the fabricated PIN devices show diode I-V characteristics and also exhibit significant IR photoresponse at 1.55 μm. In these devices and the related photoconductor counterparts, linear, ohmic contacts were readily demonstrated on top of the n-type Ge₁₋ₓSnₓ layers indicating that successful high doping of these Ge-rich semiconductors is achievable using hydride precursors developed at ASU. The in situ protocols described above using gaseous As(GeH₃)₃ reactants enable facile incorporation of the As atoms into the lattice at low growth temperatures of 350° C., and promote full activation of the entire dopant concentration (˜10¹⁸ cm⁻³-10²⁰ cm⁻³).

The newly developed Ge₁₋ₓSnₓ photodetector and photoconductor structures are attractive devices in their own right because they offer the possibility of a high efficiency detector (or arrays of detectors) grown directly on post-metallized CMOS circuits, compatible with conventional optical fiber communications wavelengths from 1.3 μm-1.6 μm. In this case, the addition of 2 at. % Sn to Ge increases the absorption at λ=1.55 μm by an order of magnitude, as shown in FIG. 5.

The above-described invention possesses numerous advantages as described herein and in the referenced appendices. The invention in its broader aspects is not limited to the specific details, representative devices, and illustrative examples shown and described. Accordingly, departures may be made from such details without departing from the spirit or scope of the general inventive concept.

We claim:

1. A infrared detector comprising
a substrate comprising a Si surface layer;
an optional first Ge₁₋ₓSnₓ layer formed directly over the Si surface layer;
an optional intrinsic Ge₁₋ₓSnₓ layer formed directly over the Si surface layer or, when present, the first Ge₁₋ₓSnₓ layer; and
a second Ge₁₋ₓSnₓ layer formed directly over, when present, the intrinsic Ge₁₋ₓSnₓ layer or, when present, the first Ge₁₋ₓSnₓ layer, or the Si surface layer;
wherein
one of (i) the Si surface layer or the first Ge₁₋ₓSnₓ layer and (ii) the second Ge₁₋ₓSnₓ layer is p-doped and the other of (i) and (ii) is n-doped, provided that when the Si surface layer is doped and the first Ge₁₋ₓSnₓ layer is present, then the Si surface layer and the first Ge₁₋ₓSnₓ layer are both n-doped or are both p-doped.

2. The infrared detector of claim 1, comprising
a substrate comprising a Si surface layer;
an optional first Ge₁₋ₓSnₓ layer formed directly over the Si surface layer;
an intrinsic Ge₁₋ₓSnₓ layer formed directly over the Si surface layer or, when present, the first Ge₁₋ₓSnₓ layer; and
a second Ge₁₋ₓSnₓ layer formed directly over the intrinsic Ge₁₋ₓSnₓ layer;
wherein
one of (i) the Si surface layer or the first Ge₁₋ₓSnₓ layer and (ii) the second Ge₁₋ₓSnₓ layer is p-doped and the other of (i) and (ii) is n-doped, provided that when the Si surface layer is doped and the first Ge₁₋ₓSnₓ layer is present, then the Si surface layer and the first Ge₁₋ₓSnₓ layer are both n-doped or are both p-doped.

3. The infrared detector of claim 2, wherein the intrinsic Ge₁₋ₓSnₓ layer has a thickness of about 0.1 μm to about 10 μm.

4. The infrared detector of claim 2 wherein the intrinsic Ge₁₋ₓSnₓ layer and the second Ge₁₋ₓSnₓ layer are each relaxed.

5. The infrared detector of claim 1, comprising
a substrate comprising a Si surface layer;
an optional first Ge₁₋ₓSnₓ layer formed directly over the Si surface layer; and
a second Ge₁₋ₓSnₓ layer formed directly over, when present, the first Ge₁₋ₓSnₓ layer, or the Si surface layer;
wherein
one of (i) the Si surface layer or the first Ge₁₋ₓSnₓ layer and (ii) the second Ge₁₋ₓSnₓ layer is p-doped and the other of (i) and (ii) is n-doped, provided that when the Si surface layer is doped and the first Ge₁₋ₓSnₓ layer is present, then the Si surface layer and the first Ge₁₋ₓSnₓ layer are both n-doped or are both p-doped.

6. (canceled)

7. (canceled)

8. (canceled)

9. The infrared detector of claim 1 wherein the substrate is an intrinsic Si substrate or a compensated Si substrate.

10. (canceled)

11. (canceled)

12. (canceled)

13. (canceled)

14. (canceled)

15. (canceled)

16. The infrared detector of claim 1, wherein the second Ge₁₋ₓSnₓ layer has a thickness of about 10 nm to about 1000 nm.

17. The infrared detector of claim 1, wherein the first Ge₁₋ₓSnₓ layer is present and has a thickness of about 10 nm to about 1000 nm.

18. (canceled)

19. The infrared detector of claim 1, wherein x is about 0.01 to about 0.20.

20. (canceled)

21. The infrared detector of claim 19, wherein x is about 0.01 to about 0.05.

22. (canceled)

23. The infrared detector of claim 1, further comprising an insulating layer formed over the second Ge₁₋ₓSnₓ layer.

24. The infrared detector of claim 1, further comprising at least one first electrode in electrical contact with the Si surface layer or the first Ge₁₋ₓSnₓ layer.

25. The infrared detector of claim 1, further comprising at least one second electrode in electrical contact with the second Ge₁₋ₓSnₓ layer.

26. The infrared detector of claim 1 having an infrared photoresponse between about 1000 nm and about 4000 nm.

27. The infrared detector of claim 1 having an external quantum efficiency in the L-telecommunication window of about 1×10⁻³ to about 1×10⁻² under a bias of about 0.10 V to about 0.20 V.

28. The infrared detector of claim 1 having an external quantum efficiency in the U-telecommunication window of about 1×10⁻³ to about 1×10⁻² under a bias of about 0.10 V to about 0.20 V.

29. An avalanche photodetector comprising an infrared detector according to claim 1.

30. A photonic circuit element comprising an infrared detector of claim 1, and a waveguiding structure in optical communication with the infrared detector.

31. The photonic circuit element of claim 30, further comprising a light emitting diode in optical communication with the waveguiding structure.

32. A detector array comprising a plurality of infrared detector elements according to claim 1 arranged in a predetermined arrangement.

33. The detector array of claim 32, wherein the infrared detector elements are arranged in a 2-D grid.

34. The detector array of claim 32, wherein the infrared detector elements are arranged in a line.

35. A method for fabricating an infrared detector comprising
providing a substrate comprising a Si surface layer;
optionally forming a first doped Ge₁₋ₓSnₓ layer over the Si surface layer;
optionally forming an intrinsic Ge₁₋ₓSnₓ layer over the Si surface layer or, when present, the first doped Ge₁₋ₓSnₓ layer; and
forming a second doped Ge₁₋ₓSnₓ layer over the intrinsic Ge₁₋ₓSnₓ layer, when present, or the first doped Ge₁₋ₓSnₓ layer, when present, or the Si surface layer;
wherein one of (i) the Si surface layer or the first doped Ge₁₋ₓSnₓ layer and (ii) the second doped Ge₁₋ₓSnₓ layer is p-doped and the other of (i) and (ii) is n-doped,
provided that when the Si surface layer is doped and the first doped Ge₁₋ₓSnₓ layer is present, then the Si surface layer and the first doped Ge₁₋ₓSnₓ layer are both n-doped or are both p-doped.

36. The method of claim 35, comprising
providing a substrate comprising a Si surface layer;
optionally forming a first doped Ge₁₋ₓSnₓ layer over the Si surface layer;
forming an intrinsic Ge₁₋ₓSnₓ layer over the Si surface layer or, when present, the first doped Ge₁₋ₓSnₓ layer; and
forming a second doped Ge₁₋ₓSnₓ layer over the intrinsic Ge₁₋ₓSnₓ layer,
wherein one of (i) the Si surface layer or the first doped Ge₁₋ₓSnₓ layer and (ii) the second doped Ge₁₋ₓSnₓ layer is p-doped and the other of (i) and (ii) is n-doped,
provided that when the Si surface layer is doped and the first doped Ge₁₋ₓSnₓ layer is present, then the Si surface layer and the first doped Ge₁₋ₓSnₓ layer are both n-doped or are both p-doped.

37. The method of claim 35, comprising
providing a substrate comprising a Si surface layer;
optionally forming a first doped Ge₁₋ₓSnₓ layer over the Si surface layer;
forming a second doped Ge₁₋ₓSnₓ layer over the first doped Ge₁₋ₓSnₓ layer, when present, or the Si surface layer;
wherein one of (i) the Si surface layer or the first doped Ge₁₋ₓSnₓ layer and (ii) the second doped Ge₁₋ₓSnₓ layer is p-doped and the other of (i) and (ii) is n-doped,
provided that when the Si surface layer is doped and the first doped Ge₁₋ₓSnₓ layer is present, then the Si surface layer and the first doped Ge₁₋ₓSnₓ layer are both n-doped or are both p-doped.

38-55. (canceled)
